(19) United States
(12) Patent Application Publication
(10) Pub. No.: US 2011/0090646 A1
(43) Pub. Date: Apr. 21, 2011

(54) Power Supply Fixing Device

(76) Inventor: Deng-Hsi CHEN, Liu-Tu Industrial Park (TW)

(21) Appl. No.: 12/422,049

(22) Filed: Apr. 10, 2009

(51) Int. Cl. H05K 5/02

(52) U.S. Cl. 361/679.58

(57) ABSTRACT

A power supply fixing device, which enables a power supply to be effectively fixed, wherein one end of the power supply fixing device is movable assembled to one panel within a computer case, and then a press surface is used to enable the position of the power supply to be quickly fixed. A hook portion formed at another end of the fixing device is used to hook onto another surface of the computer case, thereby fixedly securing the entire power supply. The complete operational process dispenses with the need for the assistance of hand tools, thus effectively increasing convenience of assembling and disassembling a power supply.

### BACKGROUND OF THE INVENTION

(a) Field of the Invention

The present invention relates to a power supply fixing device which can be assembled to a computer case, and more particularly provides a power supply fixing device which enables completing assembly and disassembly of a power supply without the need for hand tools.

(b) Description of the Prior Art

Many types of electronic devices are assembled within a general computer, such as a motherboard, CD-ROM (compact disk—read only memory) drives, a power supply, and so on. Referring to FIG. 1, which shows an elevational external view of a computer case of the prior art, and as depicted in the drawing, a power supply 101 is assembled at the position of the rear side surface within a computer case 10. The power supply 101 enables electric power to be supplied to the electronic devices assembled within the computer case 10. When installing the power supply 101 within the computer case 10 of the prior art, the power supply 101 is first disposed close to the rear side surface within the computer case 10, and then a plurality of screws 11 are used to tightly fasten the power supply 101 to the rear side surface of the computer case 10 with the assistance of a hand tool. Hence, a user requiring the assistance of a hand tool when assembling or disassembling the power supply 101 clearly complicates the assembly and disassembly process. Moreover, such an assembly method of the prior art only enables one end of the power supply 101 to be fixedly secured, thus, easily resulting in vibration and noise when the main computer is running.

### SUMMARY OF THE INVENTION

In light of the aforementioned problems, the main objective of the present invention is to provide a fixing device which enables a power supply to be effectively fixed within a computer case without the need for hand tools.

In order to achieve the aforesaid objective, a power supply fixing device of the present invention primarily uses a hook portion formed at one end thereof to hook onto a surface within a computer case and form a movable assemblage. Moreover, a press portion formed on the fixing device is used to clamp down on the power supply to fixedly secure the position thereof, after which another hook portion at another end of the fixing device is used to hook onto another surface within the computer case, thereby rapidly completing the entire assembly of the fixing device, and effectively fixing the power supply.

To enable a further understanding of said objectives and the technological methods of the invention herein, a brief description of the drawings is provided below followed by a detailed description of the preferred embodiments.

### BRIEF DESCRIPTION OF THE DRAWINGS

FIG. 1 is an elevational external view of a computer case of the prior art.

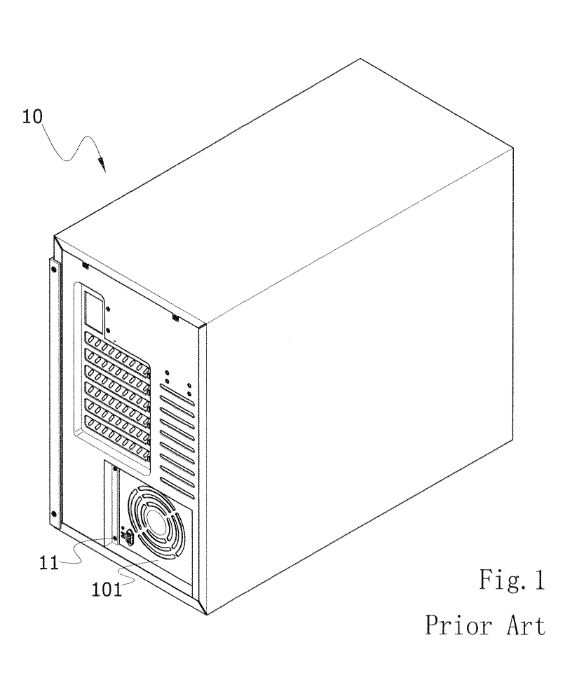

FIG. 2 is an elevational external view of the present invention.

FIG. 3 is an implementation schematic view (1) of the present invention.

FIG. 4 is an implementation schematic view (2) of the present invention.

FIG. 5 is an implementation schematic view (3) of the present invention.

FIG. 6 is an implementation schematic view (4) of the present invention.

FIG. 7 is an implementation schematic view (5) of the present invention.

FIG. 8 is another preferred embodiment of the present invention.

### DETAILED DESCRIPTION OF THE PREFERRED EMBODIMENTS

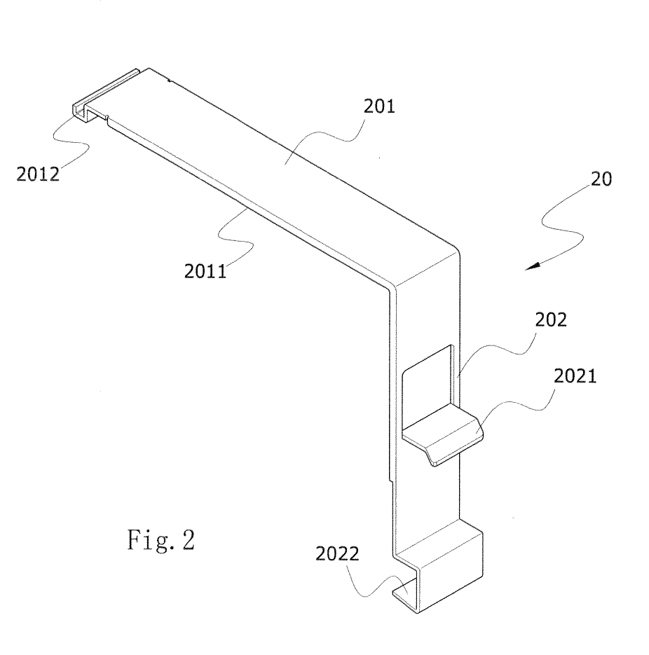

Referring to FIG. 2, which shows an elevational external view of the present invention, and a power supply fixing device 20 depicted in the drawing is primarily assembled from a press portion 201 and a plane portion 202, wherein the press portion 201 is of planar form, and the lower flat surface thereof is formed with a press surface 2011. Moreover, one end of the press portion 201 is formed with a first hook portion 2012, while the other end of the press portion 201 is formed with the plane portion 202 downwardly extending therefrom, and a raised operating portion 2021 is formed on the plane portion 202. The operating portion 2021 can be pulled aside using the fingers. Furthermore, an end of the plane portion 202 is formed with a second hook portion 2022. Referring again to the drawing depicted in FIG. 2, a joint is formed between the press portion 201 and the plane portion 202, and the two can be formed as an integral body or as two independent bodies which are mutually pivotal configured. In addition, the press portion 201 and the plane portion 202 can be configured to be mutually perpendicular, or configured to have an included angle slightly larger or slightly smaller than 90 degrees.

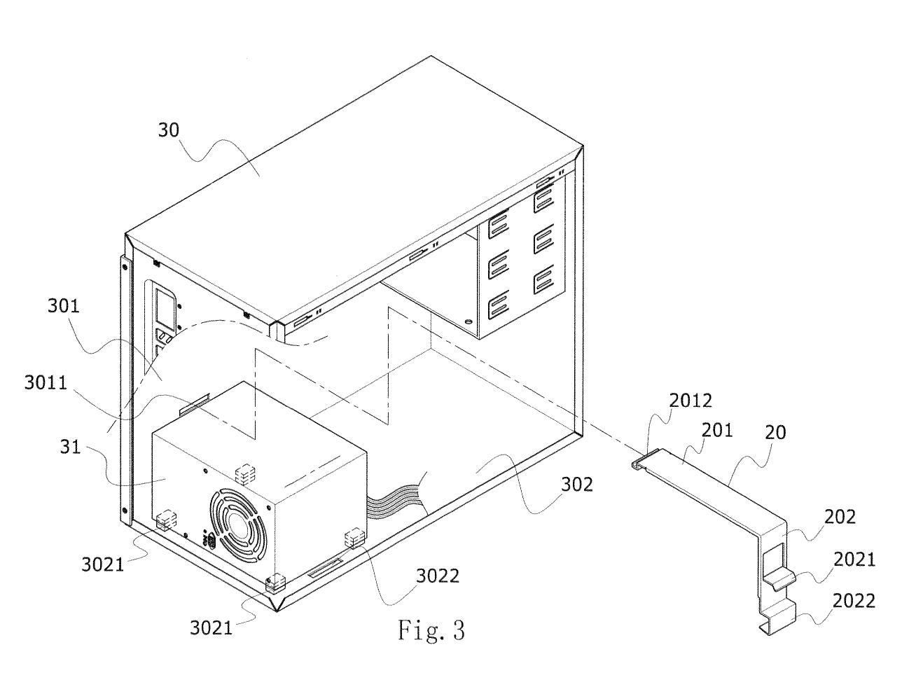

Referring to FIG. 3, which shows an implementation schematic view (1) of the present invention, wherein a first hook hole 3011 is formed in the flat surface of a side panel 301 of a computer case 30 depicted in the drawing. A plurality of elastic cushions 3021 (the present embodiment having 4 elastic cushions) are attached to the flat surface of a bottom panel 302 of the computer case 30, thereby enabling a power supply 31 to be disposed on the pads 3021, moreover, a second hook hole 3022 is formed in the flat surface of the bottom panel 302. Accordingly, the power supply fixing device 20 of the present invention enables the first hook portion 2012 at one end thereof to hook into the first hook hole 3011, and enables the second hook portion 2022 to hook into the second hook hole 3022, thereby enabling the power supply 31 disposed on the elastic cushions 3021 to be effectively fixed using the power supply fixing device 20.

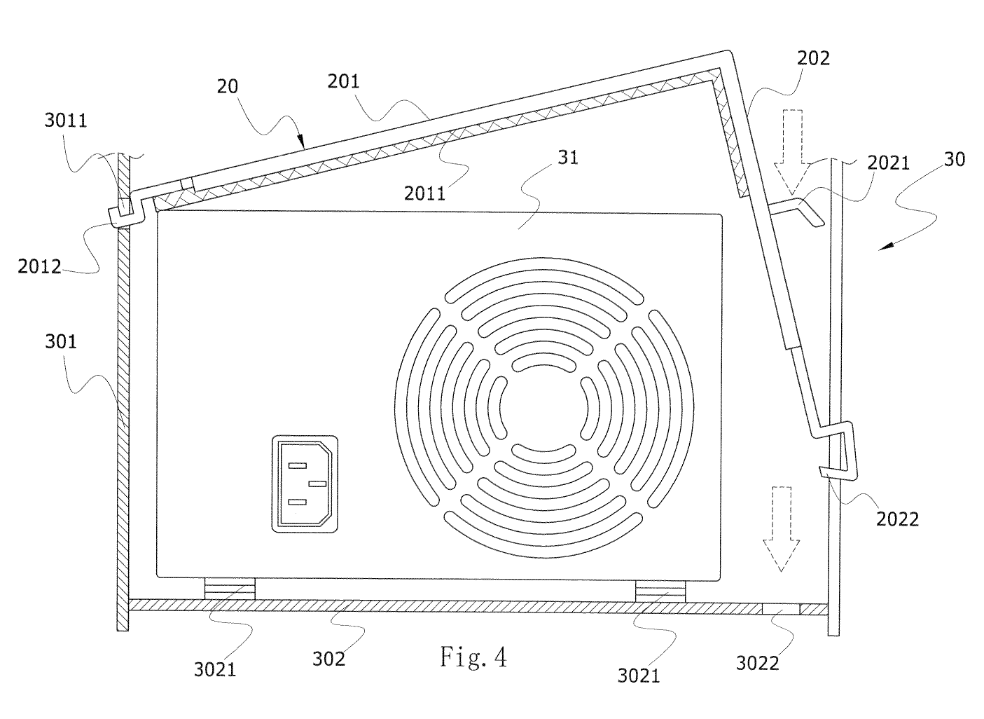

Referring to FIG. 4, which shows an implementation schematic view (2) of the present invention, and as depicted in the drawing, when implementing the present invention, the power supply 31 is first placed on the plurality of elastic cushions 3021 within the computer case 30, and then the first hook portion 2012 of the power supply fixing device 20 is hooked into the first hook hole 3011 of the computer case 30, thereby causing one end of the power supply fixing device 20 to be movable assembled to the computer case 30, after completion of which, as depicted in the drawing, a force is pressed downward (in the direction indicated by the arrow) on the operating portion 2021 to effect a downward pressure on the second hook portion 2022 and cause downward movement thereof.

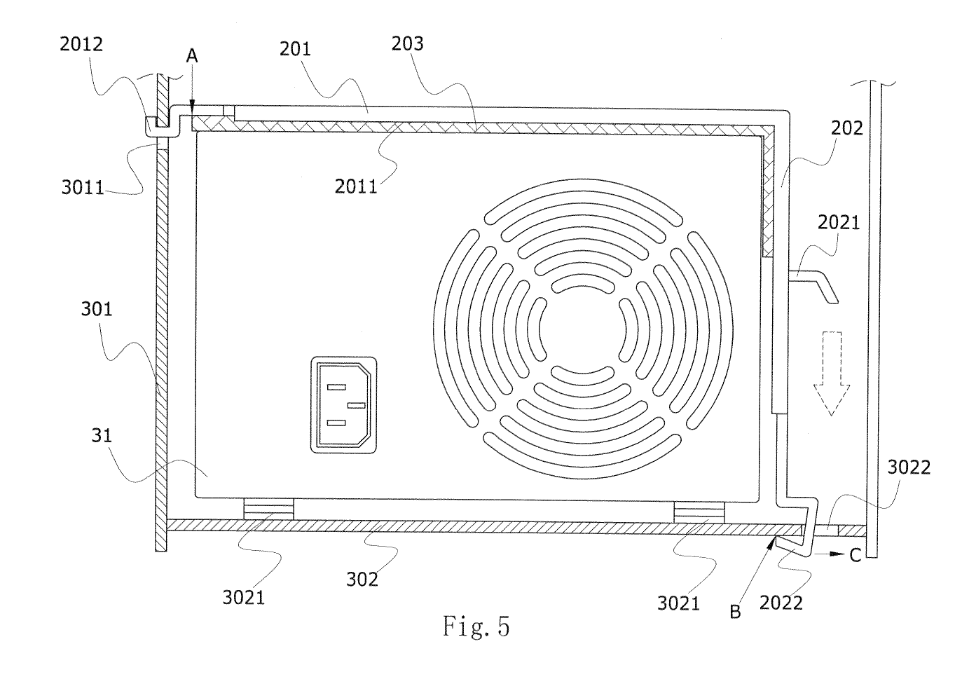

Referring to FIG. 5, which shows an implementation schematic view (3) of the present invention, wherein the first hook portion 2012 is first clasped into the first hook hole 3011, after which a forced pressed downward on the operating portion 2021 causes the press surface 2011 to gradually abut against the upper surface of the power supply 31, thereby causing a pivot A to be formed at the position where the press surface 2011 and the power supply 31 mutually abut against each other. A continuous downward force pressing on the operating portion 2021 causes the power supply 31 to be subjected to an acting force from the press surface 2011, and is thereby effectively fixed. A continuous downward force pressing on the operating portion 2021 causes a continuous downward movement of the second hook portion 2022, thereby enabling the second hook portion 2022 to appropriately hook onto the bottom portion of the second hook hole 3022 after penetrating the second hook hole 3022. Moreover, the second hook portion 2022 forms a contact point B with the bottom panel after completing clasping into the second hook hole 3022, thereby effectively fixing the power supply 31 using the power supply fixing device 20. Furthermore, when it is required to disassemble the power supply 31, then a slight force is pressed downward on the operating portion 2021, thereby enabling the second hook portion 2022 to separate from the contact point B, whereupon the operating portion 2021 is appropriately pulled in a C direction, and the slight elastic function of the power supply fixing device 20 causes the second hook portion 2022 to spring out of the second hook hole 3022 to form an unhooked state, after which the operating portion 2021 is pulled upward to cause the entire power supply fixing device 20 to assume a released state to enable completing disassembly thereof. The present invention can further comprise an elastic cushion 203 adhered to the press surface 2011 and the rear surface of the plane portion 202, thereby enabling the press surface 2011 and the rear of the plane portion 202 to abut against the power supply 31 after completing assembling the power supply fixing device 20 to the power supply 31, which further adds to tight packing on the two relative sides of the power supply 31, and thus achieves a superior fixing effect.

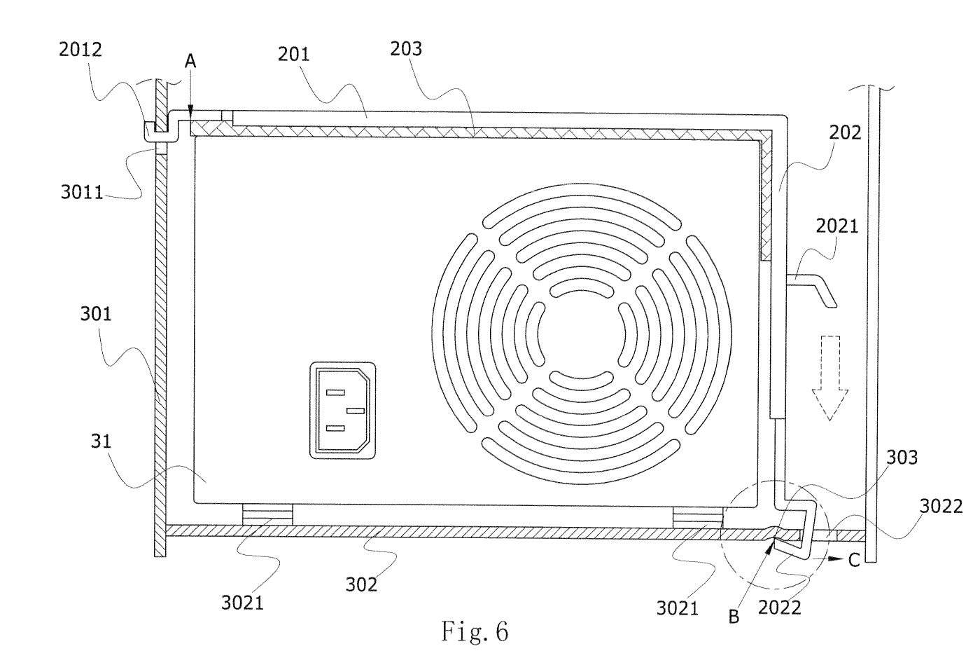

Referring to FIG. 6, which shows an implementation schematic view (4) of the present invention, and as depicted in the drawing, because a corresponding vibration is produced when a computer is running, thus, in order to ensure hooking effectiveness of the second hook portion 2022 is not affected by the vibration, the present invention is further formed with a clasp groove 303 at the position of the contact point B, thereby enabling the end of the second hook portion 2022 to appropriately clasp into the clasp groove 303 after completing hooking of the second hook portion 2022 into the hook hole 3022. Accordingly, after completing assembly of the present invention to the power supply 31, the clasp groove 303 is used to increase firmness after hooking, thereby ensuring the power supply fixing device 20 will not loosen because of vibration.

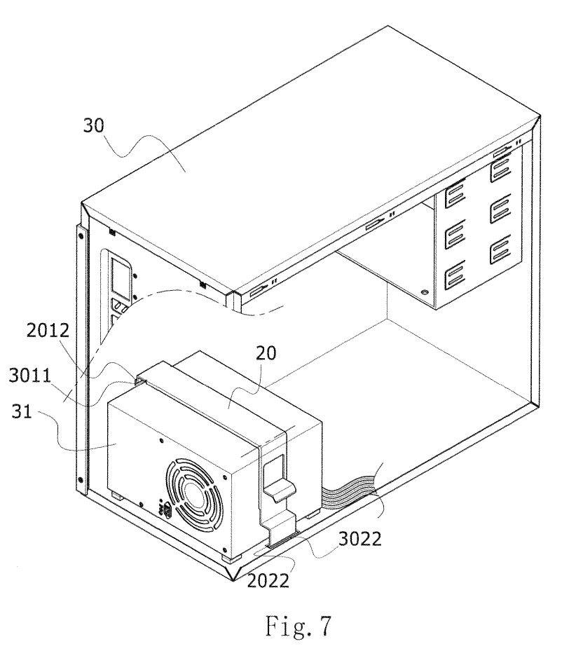

Referring to FIG. 7, which shows an implementation schematic view (5) of the present invention, wherein the first hook portion 2012 and the second hook portions 2022 at the two respective ends of the power supply fixing device 20 are used to complete assembly with the first hooks hole 3011 and the second hook holes 3022 respectively within the computer case 30, thereby enabling the power supply 31 to be fixedly secured to the computer case 30 using the power supply fixing device 20. Moreover, assembly can be completed without the need for screws or assistance of other hand tools during the assembly process, thus facilitating the user to more quickly assemble or disassemble the power supply 31.

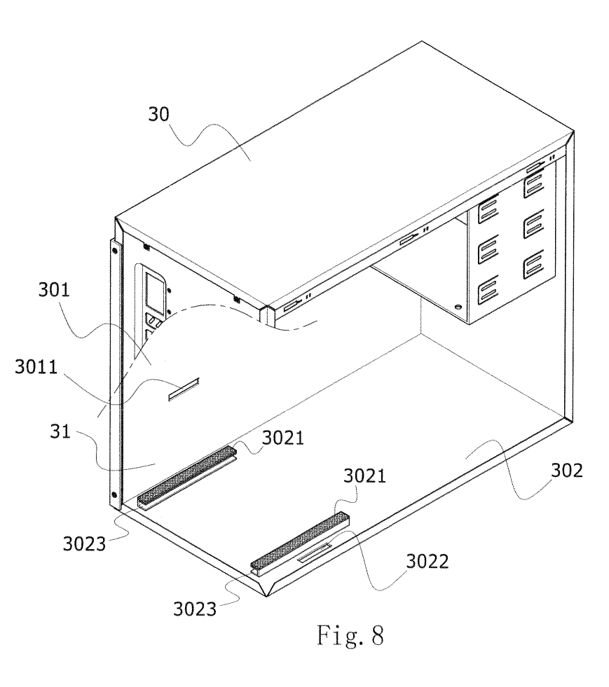

Referring to FIG. 8, which shows another preferred embodiment of the present invention, wherein the elastic cushions 3021 depicted in the drawing are formed as long strips, each of which are combined with a long backing base 3023, thereby enabling force of the bottom portion of a power supply to be evenly distributed when assembled thereon, and thus increasing overall firmness when in use.

According to what has been described above, the present invention primarily comprises a first hook hole and a second hook hole formed within a computer case, which enable a first hook portion and a second hook portion to complete respective clasping therewith and form a fixing device, thus, when assembling a power supply to a computer case, the fixing device can be used to fixedly clasp a power supply to the computer case without the need for the assistance of tools, thereby enabling fast assembly and disassembly of the power supply. Hence, based on the implementations as described, the present invention is clearly able to achieve the objective of providing a power supply fixing device which enables assembly of a power supply to a computer case without the need for the assistance of tools, and which has the functionality to realize fast assembly and the disassembly.

It is of course to be understood that the embodiments described herein are merely illustrative of the principles of the invention and that a wide variety of modifications thereto may be effected by persons skilled in the art without departing from the spirit and scope of the invention as set forth in the following claims.

What is claimed is:

1. A power supply fixing device, which is assembled within a computer case and enables a power supply to be fixedly secured to the interior of the computer case, comprising:
a press portion, one end of the press portion is formed with a first hook portion, and the first hook portion is able to clasp into a first hook hole of the computer case;
a plane portion, which is formed by extending another end of the press portion, and the plane portion is formed with an operating portion, and an end of the plane portion is formed with a second hook portion, and the second hook portion is able to clasp into a second hook hole of the computer case.

2. The power supply fixing device according to claim 1, wherein the press portion and the plane portion are formed as an integral body, and assume an inverted L-shape.

3. The power supply fixing device according to claim 1, wherein a relative pivotal relationship is assumed between the press portion and the plane portion.

4. The power supply fixing device according to claim 1, wherein a press surface is formed on the bottom surface of the press portion.

5. The power supply fixing device according to claim 4, wherein an elastic cushion is adhered to the press surface.

6. The power supply fixing device according to claim 1, wherein an elastic cushion is adhered to an inner side surface of the plane portion.

7. The power supply fixing device according to claim 1, wherein a plurality of elastic cushions are attached to the surface of the bottom panel surface of the computer case.

8. The power supply fixing device according to claim 7, wherein the elastic cushions are formed as long strips, each of which is assembled to the surface of a backing base.

9. The power supply fixing device according to claim 1, wherein, after completing clasping of the second hook portion into the second hook hole, the second hook portion forms a contact point with the surface of the bottom panel of the computer case.

10. The power supply fixing device according to claim 9, wherein a clasp groove is formed in the surface of the bottom panel corresponding to the contact point.
